(19) United States
(12) Patent Application Publication
(10) Pub. No.: US 2008/0184083 A1
(43) Pub. Date: Jul. 31, 2008

(54) Circuit and Method for Physical Defect Detection of an Integrated Circuit

(75) Inventors: Melvin Isom, Durham, NC (US); Stephen Mann, Durham, NC (US)

Correspondence Address: EDELL, SHAPIRO & FINNAN, LLC, 1901 RESEARCH BLVD., SUITE 400, ROCKVILLE, MD, 20850, US

(73) Assignee: QIMONDA NORTH AMERICA CORP., Cary, NC (US)

(21) Appl. No.: 11/668,791

(22) Filed: Jan. 30, 2007

(51) Int. Cl. G01R 31/3181; G06F 11/26

(52) U.S. Cl. 714/726; 714/E11.159

(57) ABSTRACT

A semiconductor integrated circuit device having a physical damage testing capability and a method for testing for physical damage caused during fabrication, assembly or test of the semiconductor integrated circuit are provided. A dedicated conductive test path is formed during fabrication of the integrated circuit device. The test path is routed to pass through areas of the integrated circuit which are susceptible to physical damage. A test circuit is included in the integrated circuit and is connected to the dedicated conductive test path. The test circuit tests the dedicated conductive test path for a characteristic indicative of physical damage. In one embodiment, the test circuit is a continuity circuit that measures whether there is continuity on the conductive test path. The continuity test circuit is activated in response to an externally supplied test command, such as from a test system, and to supply an output signal to a pad that is externally readable by the test system.

### BACKGROUND OF THE INVENTION

Fabrication of semiconductor integrated circuit devices involves numerous complex steps in extremely thin material. During certain steps of the fabrication process, areas of the integrated circuit are placed under physical stress that may cause physical damage to the device. For example, and not by way of limitation, devices that use a ball grid array (BGA) endure heat and mechanical stress from a solder stop mask during part of the assembly process that can cause physical damage in the form of “metal peeling” near a bond channel at the edges of the semiconductor integrated circuit die.

Currently, there is no way to test a device for physical damage during or after the fabrication process without taking the device apart which renders it completely dysfunctional. As a result, devices with physical damage may leave the factory if the physical damage does not otherwise present itself in other defects that can be detected in functional tests.

What is needed is a capability to non-destructively test integrated circuit devices for physical damage during or after fabrication.

### SUMMARY OF THE INVENTION

Briefly, a semiconductor integrated circuit device having a physical damage testing capability and a method for testing for physical damage caused during fabrication, assembly or test of the semiconductor integrated circuit are provided. During fabrication of the integrated circuit device, a dedicated conductive test path is formed that passes through areas of the integrated circuit, in particular through areas which are susceptible to physical damage during fabrication, assembly or test. In addition, a test circuit is included in the integrated circuit and is connected to the dedicated conductive test path. The test circuit tests the dedicated conductive test path for a characteristic indicative of physical damage. In one embodiment, the test circuit is a continuity circuit that measures whether there is continuity on the conductive test path. If there is no continuity on the conductive test path, then the device is said to have physical damage since a break in the conductive test path also likely means that other functional structures in the integrated circuit are physically damaged. The continuity test circuit is activated in response to an externally supplied test command, such as from a test system, and to supply an output signal to a pad that is externally readable by the test system.

The test circuit may take on any of a number of forms. In one embodiment, the test circuit comprises at least one pull-down transistor that is connected to the dedicated conductive test path. A command is supplied to the pull-down transistor which causes a signal level on the conductive test path to go low when there is a break in the continuity of the conductive test path.

### BRIEF DESCRIPTION OF THE DRAWINGS

FIG. 1 is an enlarged view from above of part of a semiconductor integrated circuit having physical damage caused during fabrication.

FIG. 2 is an enlarged view from above showing an example of a semiconductor integrated circuit containing a dedicated conductive test path that passes through areas which are susceptible to physical damage during fabrication, assembly or test according to an embodiment of the invention.

FIG. 3 is an enlarged view from above showing portions of the semiconductor integrated circuit of FIG. 2 and a schematic diagram of a test circuit connected to test loop segments in the integrated circuit shown in FIG. 2, according to one embodiment of the invention.

FIG. 4 is a schematic diagram of a continuity test circuit according to an embodiment of the invention.

FIG. 5 illustrates a side view of a semiconductor integrated circuit according to another embodiment of the invention.

FIG. 6 is a flow chart according to an embodiment of the invention.

### DETAILED DESCRIPTION

According to the present invention, a capability is provided to test or screen semiconductor integrated circuit devices for physical damage during and after fabrication without disassembling and destroying the integrated circuit device. Thus, a device can be tested for physical damage without destroying the device so that if the device passes the physical damage test, it can be sent to a customer with a higher confidence that it will not be returned due to degradation as a result of a physical damage failure.

In one embodiment, a conductive line is included in the design of an integrated circuit. The conductive line is a dedicated conductive test path that is used for testing for physical damage caused during fabrication. A test circuit is also provided (or may already exist) in the design of the integrated circuit. The test circuit is connected to the dedicated conductive test path to test for continuity of the conductive test path. When there is a break in the conductive test path, the test circuit will output a signal indicative thereof, which is interpreted as an indication of physical damage in the integrated circuit caused during fabrication. The physical damage may be, for example, metal peeling in the device. If the output of the test circuit indicates that there is no break in the conductive test path, then the device is deemed to pass the physical damage test. The test circuit is only functional when a test system is connected to the integrated circuit device and an appropriate test command is supplied to activate the test circuit in order to determine whether there is continuity on the conductive test path. During normal operation, the conductive test path and the test circuit have no bearing on the function of the integrated circuit device.

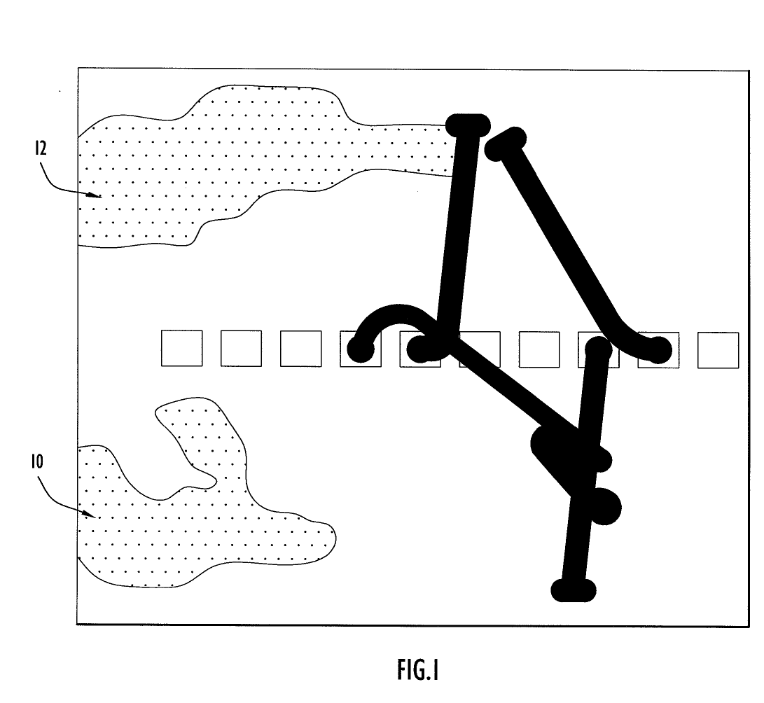

FIG. 1 illustrates an example of a semiconductor integrated circuit device that has physical damage as shown at reference numerals 10 and 12. The physical damage shown at 10 and 12 may be metal peeling and is one example of physical damage that may occur during device fabrication. The dark large connection elements in FIG. 1 are wire bonds that connect signal pads to the lead frame of the component.

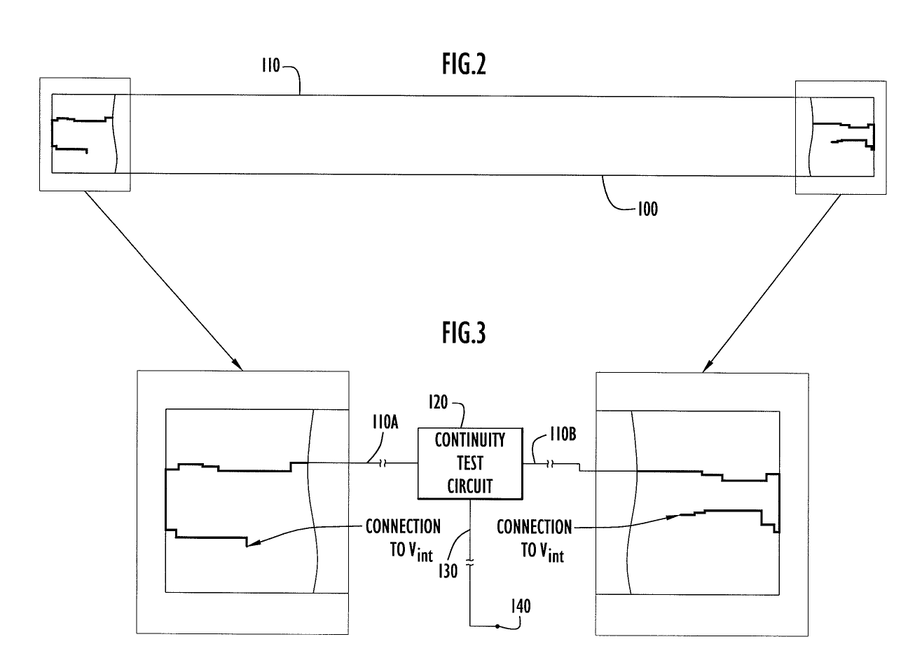

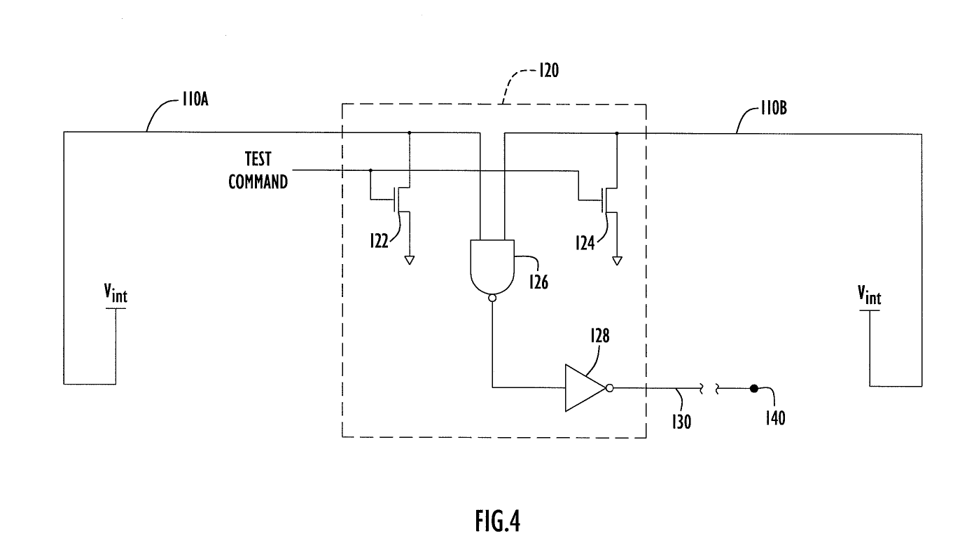

Turning to FIGS. 2 and 3, a semiconductor integrated circuit device 100 is shown according to one embodiment of the invention. A dedicated conductive test path or trace (e.g., metal wire) 110 is provided that passes through one or more areas which are susceptible to physical damage, such as along edges of the die. The dedicated conductive test path 110 is a loop formed by first and second loop portions or segments 110A and 110B, respectively, which pass through different areas of the integrated circuit.

FIG. 3 illustrates enlarged views of the device highlighting the dedicated conductive test path or trace (e.g., metal wire) 100 near the edges according to one embodiment of the invention. Also, FIG. 3 schematically shows that a continuity test circuit 120 is provided on the integrated circuit 110 between the first and second loop portions 110A and 110B. One end of loop portion 110A is connected to the continuity test circuit 120 and the other end is connected to an on-chip power supply Vint. Similarly, one end of loop portion 110B is connected to the continuity test circuit 120 and the other end is connected to the power supply Vint. An output of the continuity test circuit 120 is connected by a conductive trace 130 and in turn to an external pad 140. The first and second loop portions 110A and 110B are laid out to pass through areas of the device 100 that are known or suspected of experiencing stress during fabrication, assembly or test that could lead to physical damage. For example, the loop portions 110A and 110B may be routed to pass near edges of the integrated circuit die near a bond channel for adjacent layers of the device. The dedicated conductive test path is “dedicated” in that it serves no function other than to facilitate testing for physical damage to the device. It is not used in any way during normal operation of the device.

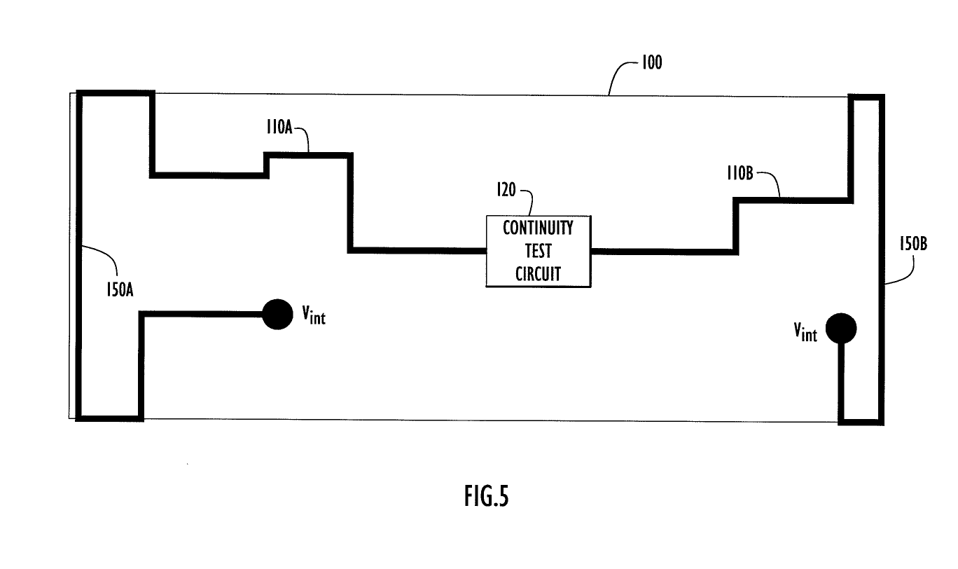

The continuity circuit 120 is shown in greater detail in FIG. 4 according to one embodiment of the invention. The continuity circuit 120 comprises first and second transistors 122 and 124 in a pull-down configuration. Transistor 122 is connected to the first loop portion 110A and transistor 124 is connected to the second loop portion 110B. The gates of the first and second transistors 122 and 124 are connected to a conductive trace that is in turn connected to receive a test command that activates the continuity test circuit 120. The test command may originate from on-board test control circuitry that is in turn activated by an external tester device when connected to the integrated circuit device 100, or may originate directly from the external test device. A NAND gate 126 has two inputs, one of which is connected to an end of the first loop portion 110A and the other of which is connected to an end of the second loop portion 110B. The output of the NAND gate 126 is connected to an inverter 128 and the output of the inverter 128 is connected to the conductive trace 130 that leads to the pad 140.

In operation, a test command is supplied to the continuity circuit 120 and the output of the continuity circuit 120 is read at the pad 140. The test command is a signal that, when enabled, causes one (or both) of the transistors 122 or 124 to assert a low signal. If either (or both) output of the transistors 110A and 110B remains low, then the output of the NAND gate 126 goes high and consequently the output of the inverter 128 will go low. Thus, when the test command is applied to the continuity circuit 120, and the output at the pad 140 is low, this indicates that there is a break either or both loop portions 110A and 110B, representative of physical damage to the integrated circuit 100. Thus, the physical damage test would fail. On the other hand, if the output of the continuity circuit 120 at pad 140 is high when the test command is enabled, this indicates that there is no break in either of the loop portions 110A and 110B and therefore the physical damage test would pass.

The continuity test circuit 120 is only one example of a means for testing a break in the dedicated conductive test path 110. With reference to FIG. 4, another method may be to provide resistors in place of the pull-down transistor devices 122 and 124, and to connect the test command to the end of a loop segment instead of Vint. In this case, when the test command is high and the conductive test path is unbroken, the inputs to NAND gate 126 would be high, indicating that the semiconductor integrated circuit passes the physical defect test. Further still, a complementary circuit may be used where ground is used in place of Vint, pull-up transistors in place of pull-down transistors 122 and 124, and a NOR gate in place of the NAND gate 126.

The routing of the dedicated conductive test path 100 may vary across different types of integrated circuits depending of the routing needs as well as function of the integrated circuit device. FIG. 5 is a side view of a semiconductor integrated circuit device and illustrating another embodiment of the invention. In this embodiment, the loop portions 110A and 110B travel the entire width of the integrated circuit device 100 at the edges of the die. For example, loop portion 110A has a length portion 150A that is near one edge of the die and loop portion 110B has a length portion 150B that is along another edge of the die. Still another alternative is to route the conductive test path entirely around the outer edge of the integrated circuit device.

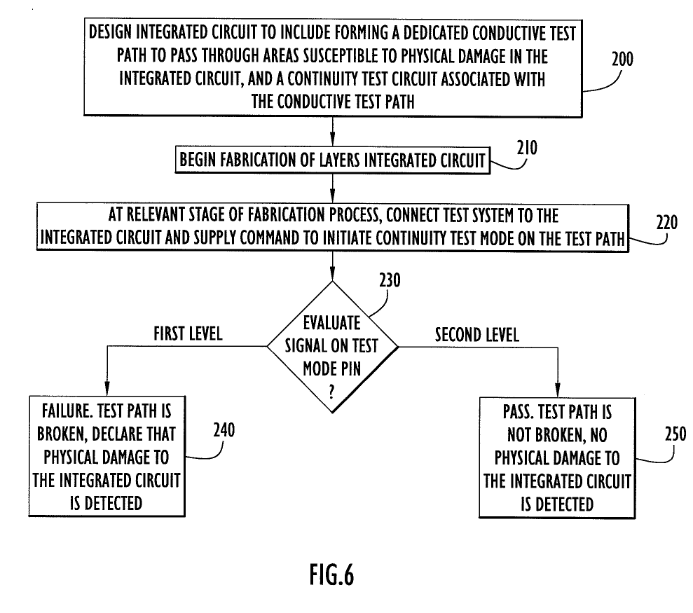

FIG. 6 illustrates a flow chart depicting a method for providing the physical damage testing capability according to embodiments of the present invention. At 200, the integrated circuit device is designed to include forming a dedicated conductive test loop or path that passes through areas susceptible to physical damage. In addition, the device is designed to include a continuity test circuit that is connected to the dedicated conductive test path such as shown in FIG. 4. Thus, the digital data used during fabrication to build the integrated circuit device includes information describing the characteristics of and location of the dedicated conductive test path and the continuity test circuit. The continuity test circuit may be a circuit that is already included in the design of the integrated circuit device, and thus it is modified to connect to the dedicated conductive test path, to receive a test command to output a signal such as shown in FIG. 4.

At 210, fabrication of the device begins. At 220, during (or after) the fabrication process a test system is connected to the integrated circuit device and a test mode is initiated to activate the continuity test circuit in the device. At 230, the input on the pin of the test mode or test system that connects to the pad 140 (FIG. 4) is read to determine the status of the output of the continuity test circuit. For example, if the output signal of the continuity test circuit is not high, then at 240 the device failed the physical damage test because the output of the continuity test circuit indicates that the conductive test path is broken as a result of physical damage to the device. On the other hand, if the output of the continuity test circuit is high, then the physical damage test is passed because a high signal at the continuity test circuit output indicates that there is no break in the conductive test path.

One advantage of the present invention is that it can reduce the number of devices that leave the manufacturing facility with physical defects and are later returned by a customer who later discovers that the part is defective. The circuit and techniques described herein may be used to test a device for metal or polysilicon connector damage due to any cause.

The system and methods described herein may be embodied in other specific forms without departing from the spirit or essential characteristics thereof. The foregoing embodiments are therefore to be considered in all respects illustrative and not meant to be limiting.

What is claimed is:

1. A method for testing an integrated circuit for physical damage caused during fabrication, comprising forming a dedicated conductive test path that passes through areas of the integrated circuit, and testing the dedicated conductive test path for a characteristic indicative of physical damage.

2. The method of claim 1, wherein testing comprises testing for continuity on the dedicated conductive test path as an indication of whether there is physical damage.

3. The method of claim 1, wherein testing comprises evaluating a signal on a pin of the integrated circuit that is connected to a continuity circuit which is in turn connected to the dedicated conductive test path to test for continuity on said dedicated conductive path.

4. The method of claim 1, wherein forming comprises forming the conductive test path to pass through areas which are susceptible to physical damage during fabrication of the integrated circuit.

5. A method for testing an integrated circuit device for physical damage caused during fabrication, assembly or test, comprising supplying to the integrated circuit device a command that activates a test circuit in the integrated circuit device, and evaluating an output of the test circuit in response to the command to determine whether there is physical damage in the integrated circuit.

6. The method of claim 5, wherein evaluating comprises evaluating the output of the test circuit that indicates whether a dedicated conductive test path in the integrated circuit device is broken as a result of metal peeling or other physical damage to the integrated circuit device.

7. A semiconductor integrated circuit device, comprising a dedicated conductive test path that passes through areas of the integrated circuit which are susceptible to physical damage during fabrication, assembly or test, and a test circuit connected to the dedicated conductive test path that measures a characteristic of the dedicated conductive test path that is indicative of physical damage.

8. The device of claim 7, wherein in response to a command the test circuit measures continuity of said dedicated conductive test path and produces an output signal indicative thereof.

9. The device of claim 8, wherein the test circuit comprises a transistor connected to said dedicated conductive test path in such a manner that in response to said command the transistor asserts a signal level on the dedicated conductive test path when there is break in the dedicated conductive test path.

10. The device of claim 9, wherein said transistor is connected to said dedicated conductive test path in a pull-down configuration such that it asserts said signal as a low voltage when there is a physical break in the dedicated conductive test path, and otherwise asserts a high voltage when there is no physical break.

11. The device of claim 5, wherein said dedicated conductive test path comprises at least first and second portions that pass through different portions of the integrated circuit device, wherein one end of the first portion is connected to the test circuit and another end of the first portion is connected to a power supply, and wherein one end of the second portion is connected to the test circuit and another end of the second portion is connected to the power supply, wherein the test circuit detects a break in either or both the first loop or the second loop.

12. An integrated circuit device, comprising a conductive line that passes through areas of the integrated circuit device where it is desired to detect physical damage caused during fabrication, a test circuit connected to said conductive line that is responsive to a command to output a signal indicative of whether there is physical damage.

13. The device of claim 12, wherein the conductive line comprises first and second loop segments that pass through different regions of the device, and wherein the test circuit is connected to the first and second loop segments to detect whether there is a break in either or both of the first or second loop segments.

14. The device of claim 13, wherein the test circuit generates an output signal that indicates whether there is a break in either or both the first and second loop portions, wherein the output signal has a first level when neither of the first and second loop portions have a break and a second level when either or both the first and second loop portions have a break.

15. The device of claim 13, wherein the test circuit comprises first and second pull-down transistors, the first pull-down transistor connected to said first loop portion and the second pull-down transistor connected to said second loop portion, wherein each of the first and second transistors are responsive to said command to produce a signal at a first level when there is a break in the respective first and second loop portions.

16. The device of claim 12, wherein the conductive line passes along edges of the integrated circuit device near a bond channel.

17. A semiconductor integrated circuit, comprising conducting means for conducting current, wherein said means for conducting passes through areas of the integrated circuit where it is desired to detect physical damage caused during fabrication, assembly or test, testing means responsive to a command for outputting a signal indicative of whether there is continuity in said means for conducting.

18. The semiconductor integrated circuit of claim 17, wherein said conducting means passes along edges of the integrated circuit near a bond channel, and wherein a break in continuity of said conducting means is indicative of metal peeling damage near said bond channel.

19. The semiconductor integrated circuit of claim 17, wherein said conducting means comprises first and second loop portions that pass through different areas of the integrated circuit and that connect to said testing means.

20. The semiconductor integrated circuit of claim 19, wherein said testing means outputs a signal having a first level when there is a break in either or both of the first and second loop portions, and otherwise outputs a signal having a second level.
